(19) United States
(12) Patent Application Publication
(10) Pub. No.: US 2014/0070301 A1
(43) Pub. Date: Mar. 13, 2014

(54) SEMICONDUCTOR STORAGE DEVICE AND MANUFACTURING METHOD THEREOF

(71) Applicant: KABUSHIKI KAISHA TOSHIBA, Minato-Ku (JP)

(72) Inventors: Masahisa SONODA, Yokkaichi-Shi (JP); Koichi Matsuno, Mie-Gun (JP)

(73) Assignee: KABUSHIKI KAISHA TOSHIBA, Minato-ku (JP)

(21) Appl. No.: 13/953,066

(22) Filed: Jul. 29, 2013

(30) Foreign Application Priority Data
Sep. 10, 2012 (JP) 2012-198759

(51) Int. Cl. H01L 29/792; H01L 29/66

(52) U.S. Cl. CPC H01L 29/792; H01L 29/66833
USPC 257/324; 438/287

(57) ABSTRACT

A semiconductor storage device according to the present embodiment includes a semiconductor substrate. A plurality of memory cells are provided on the semiconductor substrate. Peripheral circuits are provided on a periphery of the memory cells. A first barrier film includes a first nitride film provided on a first gate electrode of a transistor included in the peripheral circuits. A second barrier film includes a second nitride film different from the first nitride film. The second nitride film is provided on a second gate electrode of the memory cells, respectively. Metal layers are provided on the first and second barrier films, respectively.

### CROSS REFERENCE TO RELATED APPLICATIONS

This application is based upon and claims the benefit of priority from the prior Japanese Patent Application No. 2012-198759, filed on Sep. 10, 2012, the entire contents of which are incorporated herein by reference.

### FIELD

The embodiments of the present invention relate to a semiconductor storage device and manufacturing method thereof.

### BACKGROUND

In a semiconductor storage device such as a NAND EEPROM, a metal layer is provided on an upper portion of a control gate so as to reduce a gate resistance and a word line resistance. Generally, a barrier film is provided between the control gate and the metal layer to prevent diffusion of metal. However, when a barrier film is provided between the control gate and the metal layer, an interface resistance (an EI resistance) between the control gate and the metal layer or a sheet resistance (Rs) of the metal layer occasionally increases depending on the material of the barrier film.

When the interface resistance between the control gate and the metal layer increases, an operating speed of transistors in peripheral circuits decreases. When the sheet resistance of the metal layer increases, a word line resistance of a memory cell array increases. The material of the barrier film that can reduce both the interface resistance and the sheet resistance is not discovered yet at this time.

### BRIEF DESCRIPTION OF THE DRAWINGS

FIG. 1 shows an example of a configuration of a semiconductor storage device according to a first embodiment;

FIG. 2 is a cross-sectional view showing an example of structures of the NAND string NS and the selection gate transistors SGD and SGS;

FIG. 3 is a cross-sectional view showing an example of a structure of a transistor Tr in the peripheral circuit region 2;

FIGS. 4A to 4C are cross-sectional views showing an example of a configuration of the gate electrode MCG of each memory cell MC, an example of a configuration of the gate electrode G of each transistor Tr, and an example of a configuration of a boundary portion BP;

FIG. 5 is a cross-sectional view of an example of a resistive element R using the charge accumulation layer CA;

FIG. 6 is a graph showing a result of measuring an interface resistance R_{EI} and a sheet resistance R_{S} using the resistive element R;

FIGS. 7A to 10C are cross-sectional views showing an example of a manufacturing method of the NAND flash EEPROM according to the first embodiment;

FIGS. 11A to 11C are cross-sectional views showing an example of a configuration of the gate electrode MCG of each memory cell MC, an example of a configuration of the gate electrode G of each transistor Tr, and an example of a configuration of the boundary portion BP according to the second embodiment;

FIGS. 12A to 12C are cross-sectional views showing an example of a manufacturing method of a NAND flash EEPROM according to the second embodiment; and

FIGS. 13A to 13C are cross-sectional views showing an example of a configuration of the gate electrode MCG of each memory cell MC, an example of a configuration of the gate electrode G of each transistor Tr, and an example of a configuration of a boundary portion BP.

### DETAILED DESCRIPTION

A semiconductor storage device according to the present embodiment includes a semiconductor substrate. A plurality of memory cells are provided on the semiconductor substrate. Peripheral circuits are provided on a periphery of the memory cells. A first barrier film includes a first nitride film provided on a first gate electrode of a transistor included in the peripheral circuits. A second barrier film includes a second nitride film different from the first nitride film. The second nitride film is provided on a second gate electrode of the memory cells, respectively. Metal layers are provided on the first and second barrier films, respectively.

Embodiments will now be explained with reference to the accompanying drawings. The present invention is not limited to the embodiments. In the embodiments, terms indicating upper and lower directions refer to relative directions when a direction of a surface of a semiconductor substrate on which memory cells MC are provided is assumed as an upper direction, and the term “upper direction” occasionally differs from an upper direction based on a gravitational acceleration direction.

### First Embodiment

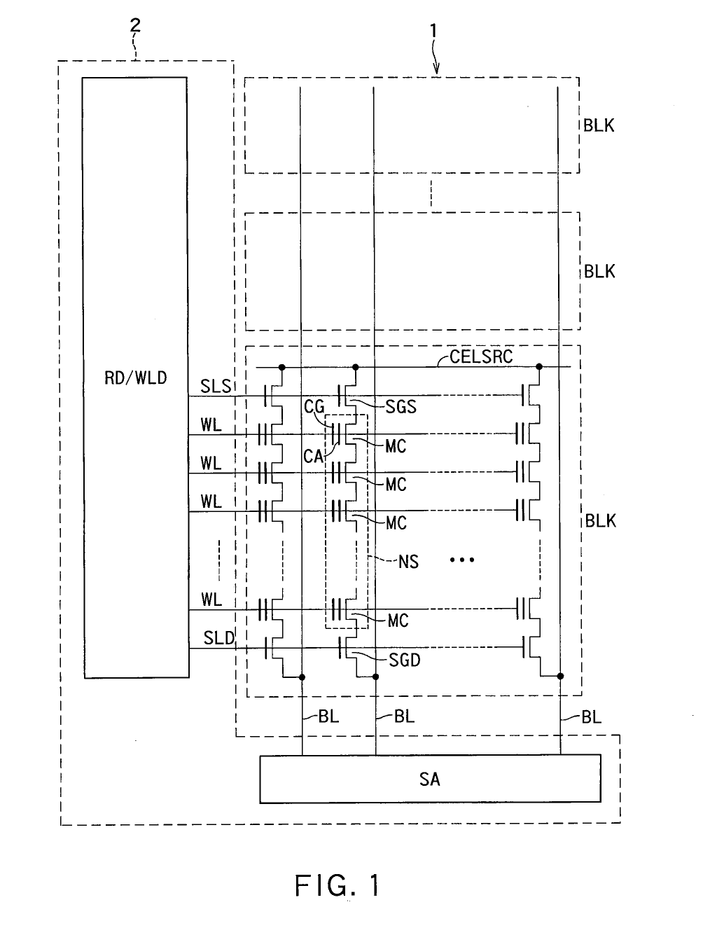

FIG. 1 shows an example of a configuration of a semiconductor storage device according to a first embodiment. The semiconductor storage device is a NAND flash memory (hereinafter, also simply “memory”), for example. The memory includes a memory cell array 1 in which a plurality of memory cells MC are arranged two-dimensionally in a matrix, and a peripheral circuit region 2 for controlling the memory cell array 1.

The memory cell array 1 includes a plurality of blocks BLK and each block BLK includes a plurality of NAND strings NS. A block BLK is a data erasure unit. Each of the NAND strings NS includes a plurality of memory cells MC connected in series. The memory cells MC on both ends of the NAND string NS are connected to selection gate transistors SGD and SGS, respectively. Each of the memory cells MC on one end of the memory cell array 1 is connected to a bit line BL via the selection gate transistor SGD, and each of the memory cells MC on the other end thereof is connected to a cell source CELSRC via the selection gate transistor SGS.

Each word line WL is connected to control gates CG of the memory cells MC arrayed in a row direction. Selection gate lines SLD and SLS are connected to gates of the selection gate transistors SGD and SGS, respectively. The word lines WL and the selection gate lines SLS and SLD are driven by a row decoder RD and a word line driver WLD.

Each bit line BL is connected to one NAND string NS via the selection gate transistor SGD. Each bit line BL is also connected to a sense amplifier circuit SA. A plurality of memory cells MC connected to one word line WL constitute a page that is a batch data-read and data-write unit.

The selection gate lines SLS and SLD drive the selection gate transistors SGS and SGD, respectively, thereby connecting the NAND strings NS between the bit lines BL and the cell source CELSRC. The word line driver WLD drives unselected word lines WL, thereby turning on unselected memory cells MC. The sense amplifier SA can thereby apply a voltage to selected memory cells MC via the bit lines BL. The sense amplifier SA can thereby detect data stored in the selected memory cells MC or write data to the selected memory cells MC.

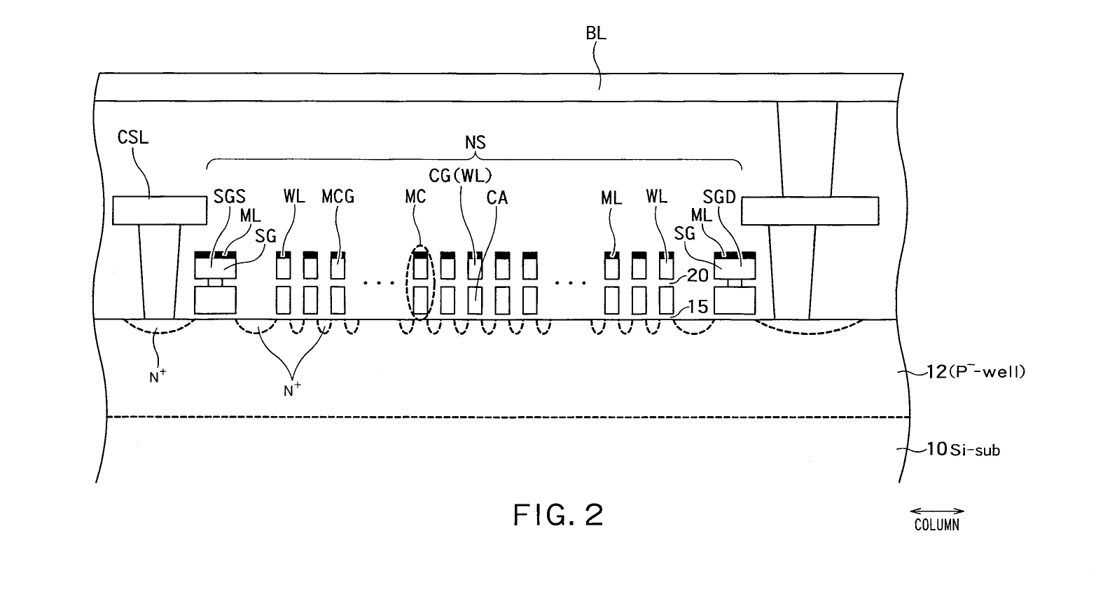

FIG. 2 is a cross-sectional view showing an example of structures of the NAND string NS and the selection gate transistors SGD and SGS. The NAND string NS is formed on a P-well 12 formed on a silicon substrate 10. A cell source line CSL is connected to the source-side selection gate transistor SGS connected to a source side of the NAND string NS. The bit line BL is connected to the drain-side selection gate transistor SGD connected to a drain side of the NAND string NS.

The two memory cells MC adjacent in a column direction share an n⁺ diffusion layer. The memory cells MC are thereby connected in series between the selection gate transistors SGD and SGS.

Each memory cell MC includes a charge accumulation layer CA provided on the silicon substrate 10 via a tunnel gate dielectric film 15 and a control gate CG provided on the charge accumulation layer CA via an inter-gate dielectric film 20.

Gate electrodes SG of the selection gate transistors SGD and SGS are made of the same material as that of the charge accumulation layer CA and the control gate CG of each memory cell MC. However, a part of the INTER-GATE DIELECTRIC film 20 between the charge accumulation layer CA and the control gate CG is removed to allow the charge accumulation layer CA and the control gate CG to be electrically connected to each other.

A metal layer ML is provided on gate electrodes MCG of the memory cells MC and the gate electrodes SG of the selection gate transistors SGD and SGS so as to reduce a gate resistance and a word line resistance. A barrier film (not shown in FIG. 2) is formed between the gate electrodes MCG, SG and the metal layer ML so as to prevent the metal material of the metal layer ML from being diffused to the gate electrodes MCG and SG. The barrier film is described later.

The gate electrode MCG and the metal layer ML extend in a row direction and also function as one word line WL.

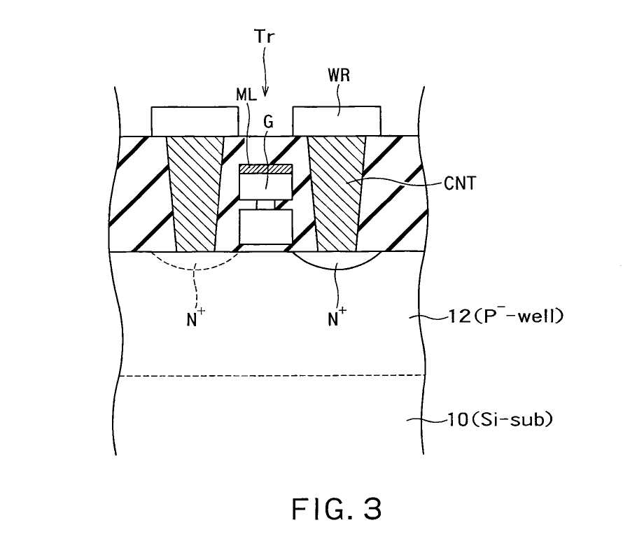

FIG. 3 is a cross-sectional view showing an example of a structure of a transistor Tr in the peripheral circuit region 2. A gate electrode G of the transistor Tr is similar in configuration to the gate electrodes SG of the selection gate transistors SGD and SGS. However, a barrier film (not shown in FIG. 3) provided between the gate electrode G and the metal layer ML differs from that provided between the gate electrode MCG or SG and the metal layer ML.

A source layer or a drain layer of the transistor Tr is electrically connected to a wiring WR via a contact plug CNT. In the peripheral circuit region 2, semiconductor devices such as transistors Tr shown in FIG. 3 are provided on the silicon substrate 10, and these semiconductor devices operate to control the memory cell array 1.

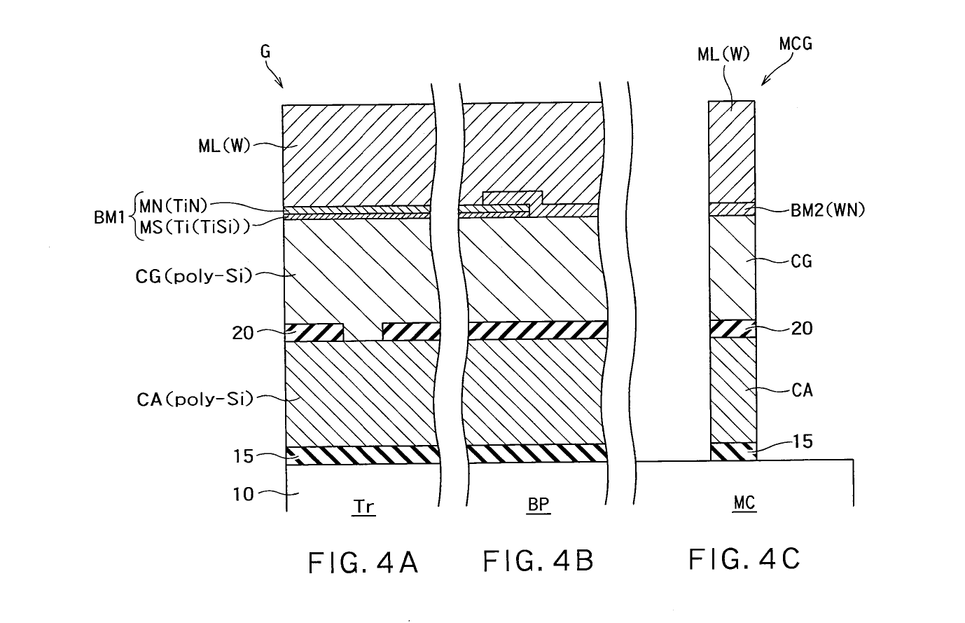

FIGS. 4A to 4C are cross-sectional views showing an example of a configuration of the gate electrode MCG of the memory cell MC, an example of a configuration of the gate electrode G of the transistor Tr, and an example of a configuration of a boundary portion BP between the memory cell array 1 and the peripheral circuit region 2 in more detail.

FIG. 4A shows the configuration of the gate electrode G of transistor Tr in the peripheral circuit region 2 in more detail. The gate electrode G serving as a first gate electrode includes the tunnel gate dielectric film 15 provided on the silicon substrate 10, the charge accumulation layer CA provided on the tunnel gate dielectric film 15, the inter-gate dielectric film 20 provided on the charge accumulation layer CA, the control gate CG provided on the inter-gate dielectric film 20, a first barrier film BM1 provided on the control gate CG, and the metal layer ML provided on the barrier film BM1.

The tunnel gate dielectric film 15 is formed by using, an insulating film, for example, a silicon oxide film. The charge accumulation layer CA is formed by using a material of, for example, polysilicon or a laminated film of polysilicon and a silicon nitride film. The inter-gate dielectric film 20 is an insulating film, for example, a silicon oxide film, a silicon nitride film, or a High-k film, and the inter-gate dielectric film 20 has an opening. The control gate CG is formed by using, for example, a conductive film made of doped polysilicon or the like. The control gate CG is disposed in the opening to electrically connect to the charge accumulation layer CA. A material of the first barrier layer BM1 is, for example, a laminated film of a metal silicide MS provided on the control gate CG and a first nitride film MN provided on the metal silicide MS. The metal silicide MS is formed by using a material of a titanium silicide film, for example. The first nitride film MN is formed by using a material of a titanium nitride film, for example. In this case, the first barrier film BM1 is the laminated film of the titanium silicide film and the titanium nitride film. The titanium silicide film is provided on the control gate CG and the titanium nitride film is provided on the titanium silicide film. While titanium is deposited on the control gate CG at a time of forming the first barrier film BM1, it is considered that the deposited titanium is actually transformed into the titanium silicide film by heat generated during processes performed by the time the NAND flash memory is completed. Therefore, although the material of the first barrier film BM1 is the laminated film of the titanium and the titanium silicide film, the material of the first barrier film BM1 in a finished product of the NAND flash memory may be regarded as the laminated film of the titanium silicide film and the titanium nitride film. The laminated film of the titanium silicide film and the titanium nitride film is referred to as “Ti(TiSi)/TiN film”. The metal layer ML is formed by using, for example, low resistance metal such as tungsten.

FIG. 4C shows the configuration of the gate electrode MCG of the memory cell MC in more detail. The gate electrode MCG serving as a second gate electrode includes the tunnel gate dielectric film 15 provided on the silicon substrate 10, the charge accumulation layer CA provided on the tunnel gate dielectric film 15, the inter-gate dielectric film 20 provided on the charge accumulation layer CA, the control gate CG provided on the inter-gate dielectric film 20, a second barrier film BM2 provided on the control gate CG, and the metal layer ML provided on the second barrier film BM2.

The materials of the tunnel gate dielectric film 15, the charge accumulation layer CA, the inter-gate dielectric film 20, the control gate CG, and the metal layer ML are similar to those of the corresponding configurations of the gate electrode G of the transistor Tr, respectively. The second barrier film BM2 is formed by using a metal nitride film, for example, a single layer film of a tungsten nitride film as a second nitride film different from the material (the first nitride film) of the first barrier film BM1. Note that the gate electrode SG of the selection gate transistor SGD or SGS is similar to the gate electrode G of the transistor Tr in a part of configuration, that is, the charge accumulation layer CA, the inter-gate dielectric film 20, the control gate CG, and the metal layer ML. However, the gate electrode SG includes the second barrier film BM2 between the control gate CG and the metal layer ML similarly to the gate electrode MCG of the memory cell MC.

FIG. 4B shows the configuration of the boundary portion BP between the memory cell array 1 and the peripheral circuit region 2. The tunnel gate dielectric film 15, the charge accumulation layer CA, the inter-gate dielectric film 20, the control gate CG, and the metal layer ML can be formed in the memory cell array 1 and the peripheral circuit region 2 in common. Therefore, the boundary portion BP is similar to the gate electrode MCG of the memory cell MC and the gate electrode G of the transistor Tr in a part of configuration, that is, the tunnel gate dielectric film 15, the charge accumulation layer CA, the inter-gate dielectric film 20, the control gate CG, and the metal layer ML.

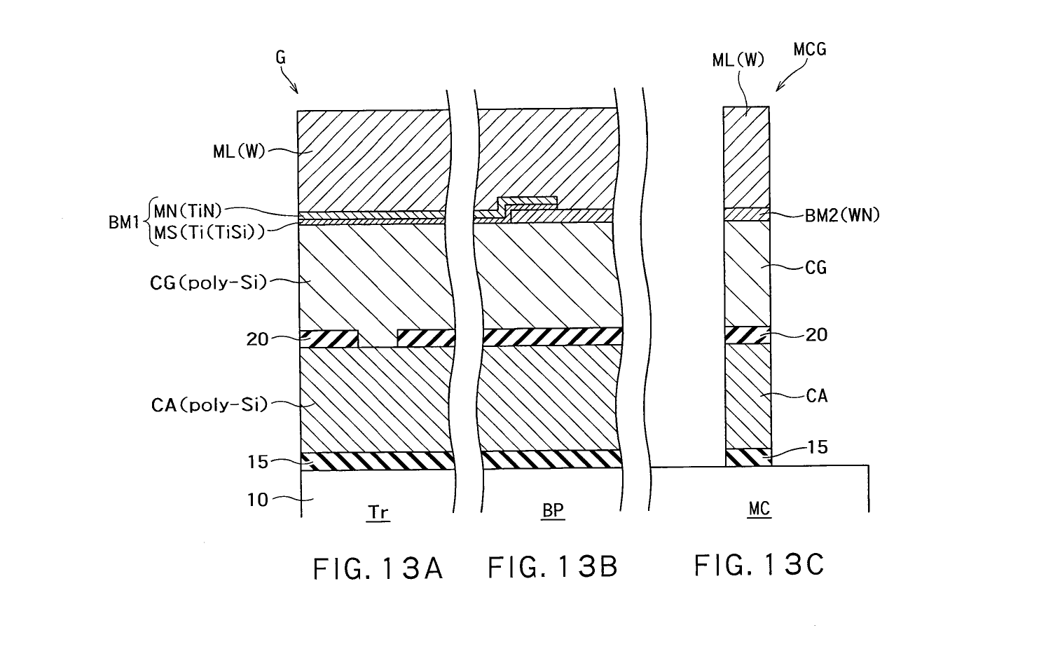

Meanwhile, the first barrier film BM1 and the second barrier film BM2 are made of different materials and configured differently from each other. Because the first barrier film BM1 and the second barrier film BM2 are formed by different processes, one of the first barrier film BM1 and the second barrier film BM2 is superimposed on the other barrier film in the boundary portion BP. In FIG. 4B, the second barrier film BM2 is superimposed on the first barrier film BM1. Note that the first barrier film BM1 is occasionally superimposed on the second barrier film BM2 depending on the manufacturing method as shown in FIG. 13B. As shown in FIGS. 13A to 13C, advantages of the first embodiment can be obtained, even if the first barrier film BM1 is superimposed on the second barrier film BM2 as shown in FIGS. 13A to 13C.

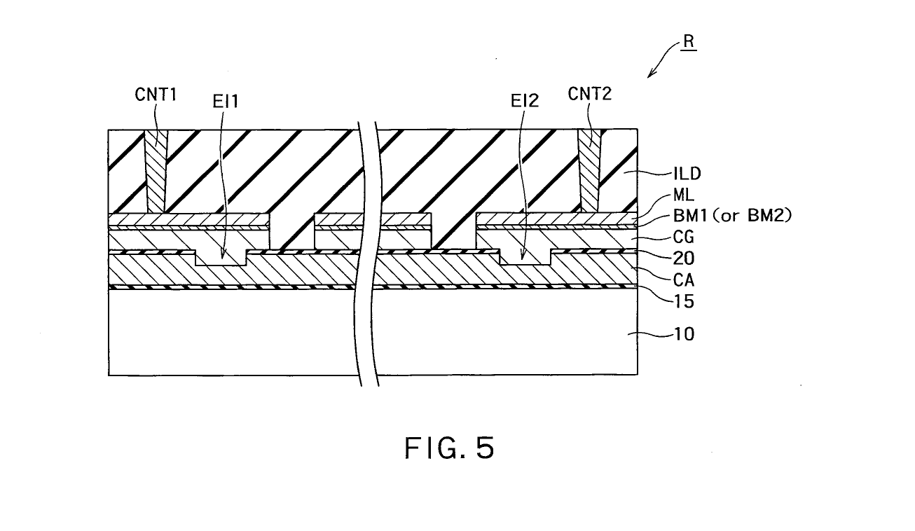

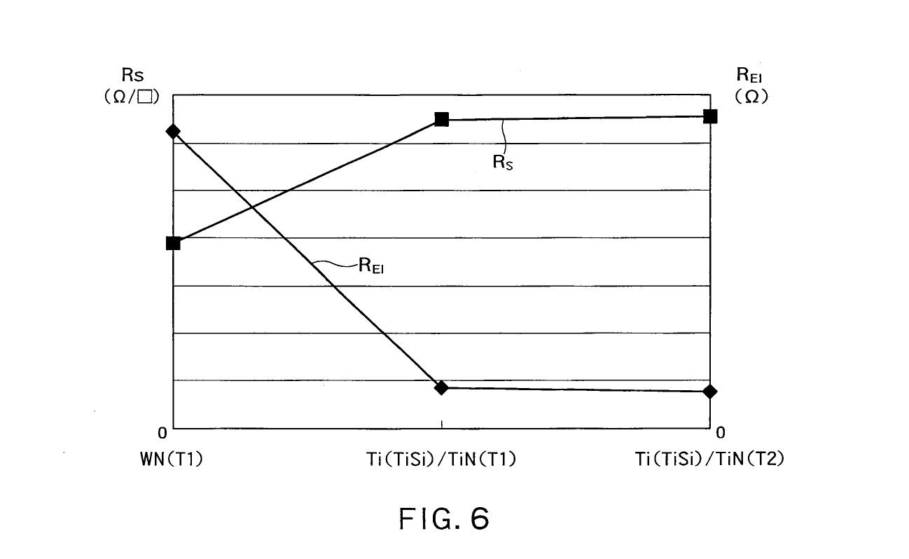

In this way, the memory according to the first embodiment includes the first barrier film BM1 that includes the Ti(TiSi)/TiN film as the first nitride film on the first gate electrode G of the transistor Tr in the peripheral circuit region 2. The memory also includes the second barrier film BM2 that includes the tungsten nitride film as the second nitride film on the second gate electrode MCG of the memory cell MC. By providing the first and second barrier films BM1 and BM2 different from each other in the memory cell array 1 and the peripheral circuit region 2, respectively, the memory exhibits the following effects as described with reference to FIGS. 5 and 6.

FIG. 5 is a cross-sectional view of an example of a resistive element R using the charge accumulation layer CA.

FIG. 6 is a graph showing a result of measuring an interface resistance R_{EI} and a sheet resistance R_{S} using the resistive element R.

The resistive element R includes contact plugs CNT1 and CNT2 connected to the metal layers ML separated from each other, respectively. The resistive element R also includes etching regions EI (Etching Inter-poly) 1 and EI2. The control gate CG is connected to the charge accumulation layer CA in the etching regions EI1 and EI2. The contact plug CNT1 is electrically connected to the charge accumulation layer CA via the etching region EI1 and electrically connected to the contact plug CNT2 via the etching region EI2. The resistive element R thereby functions as a resistive element using the charge accumulation layer CA.

In a case of using a tungsten nitride film as the barrier film between the metal layer ML and the control gate CG in such a resistive element R, the sheet resistance R_{S} of the metal layer ML was suppressed to be relatively low. But, the interface resistance R_{EI} between the metal layer ML and the control gate CG was relatively high as indicated by WN (T1) in the graph of FIG. 6. At this time, a film thickness of the tungsten nitride film was T1.

On the other hand, in a case of using a Ti(TiSi)/TiN film as the barrier film between the metal layer ML and the control gate CG, the sheet resistance R_{S} of the metal layer ML was higher than that in the case of using the tungsten nitride film. But, the interface resistance R_{EI} between the metal layer ML and the control gate CG was lower than that in the case of using the tungsten nitride film as indicated by Ti(TiSi)/TiN (T1) in the graph of FIG. 6. At this time, the film thickness of the Ti(TiSi)/TiN film was T1. This tendency was the same even when the thickness of the Ti(TiSi)/TiN film was increased to T2 (T2>T1). In this way, the sheet resistance R_{S} of the metal layer ML and the interface resistance R_{ET} between the metal layer ML and the control gate CG tend to contradict each other depending on the difference of the materials of the barrier films BM1 and BM2.

The sheet resistance R_{S} of the metal layer ML changes because a grain size of the metal layer ML differs depending on the material of the barrier film that serves as a ground (seed layer) of the metal layer ML. For example, when the barrier film is a Ti(TiSi)/TiN film, the grain size of the metal layer ML (tungsten, for example) is relatively small. In contrast, when the barrier film is a tungsten nitride film, the grain size of the metal layer ML is relatively large. As can be understood, the sheet resistance R_{S} in the case where the barrier film is the Ti(TiSi)/TiN film is higher than the sheet resistance R_{S} in the case where the barrier film is the tungsten nitride film.

When the barrier film is the Ti(TiSi)/TiN film, a silicide (TiSi) film having a relatively low resistance is formed between the TiN film and the control gate CG. When the barrier film is the tungsten nitride film, a silicon nitride film higher in resistance than the silicide (TiSi) film is formed between the tungsten nitride film and the control gate CG. As a result, the interface resistance R_{EI} in the case where the barrier film is the Ti(TiSi)/TiN film is lower than the interface resistance R_{EI} in the case where the barrier film is the tungsten nitride film.

Generally, when the interface resistance R_{EI} between the metal layer ML and the control gate CG is high, an operation speed of the transistors Tr in the peripheral circuit region 2 decreases. It is important to suppress the interface resistance R_{EI} rather than the sheet resistance R_{S} to be low because wirings in the peripheral circuit region 2 are not downscaled as compared with the word lines WL. Therefore, it is preferable that the barrier film is the first barrier film BM1 having a low interface resistance R_{EI} such as a Ti(TiSi)/TiN film in the peripheral circuit region 2 according to the first embodiment.

On the other hand, in the memory cell array 1, a line width of the word line WL is downscaled to be equal to or smaller than a half (a half pitch) of a minimum processing size (feature size) F of a lithographic technique. Furthermore, the word lines WL are longer than the wirings in the peripheral circuit region 2 because the word lines WL are provided over a plurality of memory blocks BLK within the memory cell array 1. It is important for such thin and long word lines WL to have a low sheet resistance R_{S}. Therefore, it is preferable that the barrier film is the second barrier film BM2 such as a tungsten nitride film that can realize the reduced sheet resistance R_{S} of the metal layer ML, in the memory cell array 1 according to the first embodiment.

In this way, according to the first embodiment, the first barrier film BM1 is used in the gate electrode G of the transistor Tr in the peripheral circuit region 2, and the second barrier film BM2 different from the first barrier film BM1 is used in the gate electrode MCG of each memory cell MC. This can realize both an improvement in an operation speed of each transistor Tr in the peripheral circuit region 2 and a reduction in a sheet resistance R_{S} of each word line WL in the memory cell array 1.

In the peripheral circuit region 2, the interface resistance R_{EI} increases when the tungsten nitride film is used as the barrier film. To deal with this, it is considered to directly connect the contact plugs CNT1 and CNT2 to the charge accumulation layer CA. However, in this case, it becomes to form deep contact holes (not shown) that reach the charge accumulation layer CA at a time of forming the contact plugs CNT1 and CNT2. It is difficult to form such deep contact holes simultaneously with relatively shallow contact holes used for contact plugs connected to the metal layer ML. As a result, it may be to add a lithographic process and an etching process so as to form deep contact holes that reach the charge accumulation layer CA. Furthermore, the interface resistance R_{EI} of the gate electrode G of the transistor Tr remains high. Therefore, it is effective to provide the barrier films BM1 and BM2 different from each other in the peripheral circuit region 2 and the memory cell array 1, respectively.

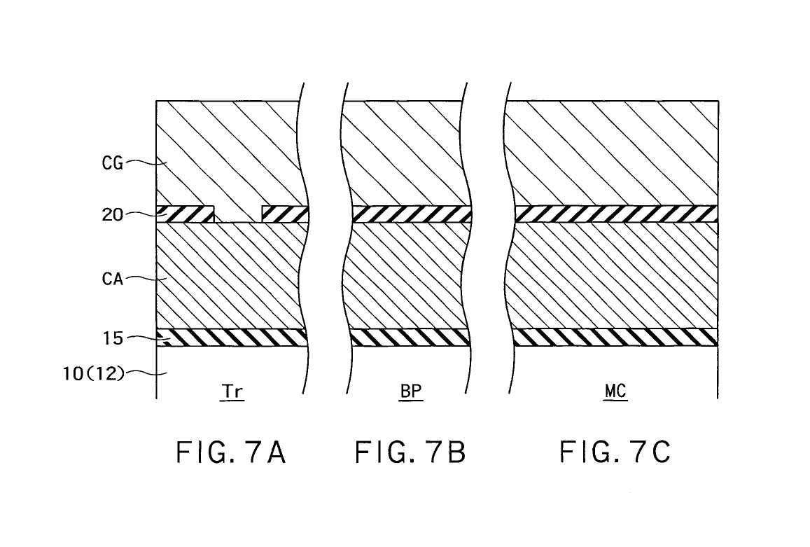

FIGS. 7A to 10C are cross-sectional views showing an example of a manufacturing method of the NAND flash EEPROM according to the first embodiment.

First, the tunnel gate dielectric film 15 is formed on the silicon substrate 10. For example, a silicon oxide film is used as the tunnel gate dielectric film 15, and the silicon oxide film can be formed by oxidizing the silicon substrate 10. In regions of the selection gate transistors SGS, SGD and the peripheral circuit region 2, a gate dielectric film different from the tunnel gate dielectric film 15 can be formed.

Next, the material of the charge accumulation layer CA is deposited on the tunnel gate dielectric film 15. The material of the charge accumulation layer CA is formed by using, for example, polysilicon or a laminated film of polysilicon and a silicon nitride film.

After forming STI (Shallow Trench Isolation) (not shown) as element isolation, the inter-gate dielectric film 20 is then deposited on the charge accumulation layer CA. The inter-gate dielectric film 20 is an insulating film, for example, a silicon oxide film, a silicon nitride film, or a High-k film. A part of the inter-gate dielectric film 20 provided for the transistors Tr is removed. When this inter-gate dielectric film 20 is etched, a part of the inter-gate dielectric film 20 provided for the selection gate transistors SGS and SGD is also removed. Furthermore, the inter-gate dielectric film 20 in the etching regions EI1 and EI2 of the resistive element R is also removed.

Next, the material of the control gate CG is deposited on the inter-gate dielectric film 20. The material of the control gate CG is, for example, a conductive film made of doped polysilicon or the like. The material of the control gate CG is electrically connected to the charge accumulation layer CA in portions from which the inter-gate dielectric film 20 is removed for the transistors Tr, the selection gate transistors SGS and SGD, and the resistive element R. With this process, the materials of the gate electrodes (CA and CG) are formed on the silicon substrate 10 as shown in FIGS. 7A to 7C.

The first barrier film BM1 is then deposited on the control gate CG. The first barrier film BM1 includes the metal film MS formed on the control gate CG and the first nitride film MN formed on the metal film MS. The metal film MS is considered to be transformed into the metal silicide after deposition. For example, the metal film MS is formed by using a titanium film and transformed into a titanium silicide film after the deposition. The first nitride film MN is formed by using, for example, a titanium nitride film. A film thickness of the titanium film is about 2 nm, for example. A film thickness of the titanium nitride film is about 10 nm, for example.

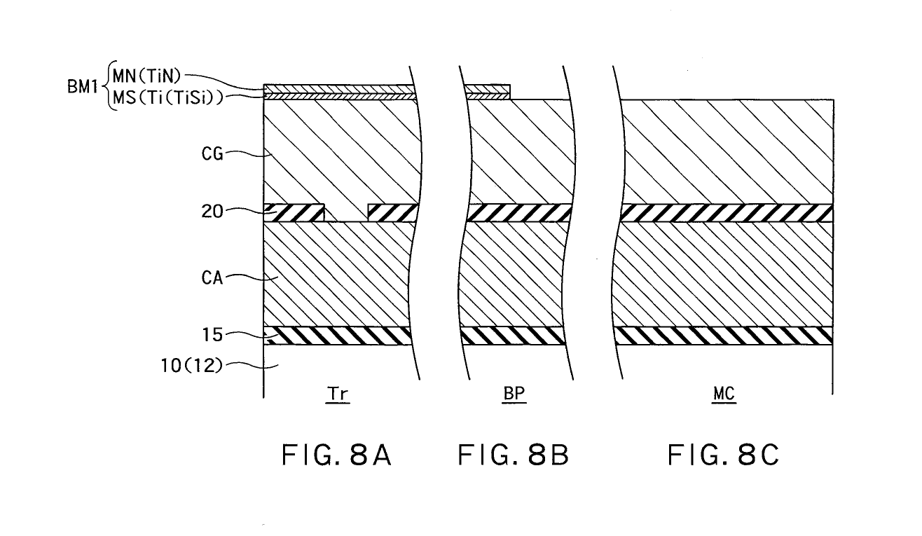

Next, by using a lithographic technique and a RIE (Reactive Ion Etching) method, the material of the first barrier film BM1 present in a region of the memory cell array 1 is removed and the first barrier film BM1 is left on the material of the control gate CG in the peripheral circuit region 2, as shown in FIGS. 8A to 8C.

The material of the second barrier film BM2 is then deposited on the materials of the control gate CG and the first barrier film BM1. The material of the second barrier film BM2 is formed by using the second nitride film different from the material (the first nitride film) of the first barrier film BM1. The second barrier film BM2 is formed by using, for example, the metal nitride film such as a tungsten nitride film. A film thickness of the tungsten nitride film is about 10 nm, for example.

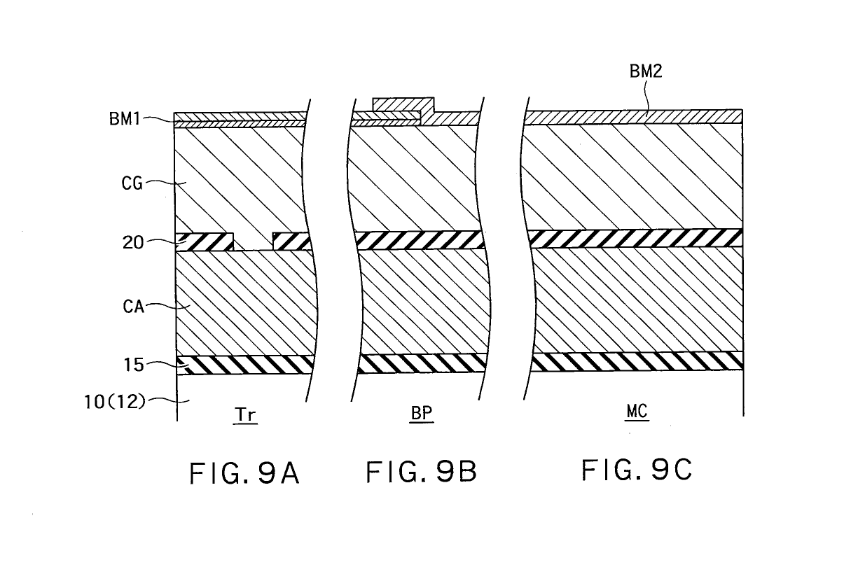

Next, by using a lithographic technique and a RIE method, the material of the second barrier film BM2 in the peripheral circuit region 2 is removed and the second barrier film BM2 is left on the material of the control gate CG in the memory cell array 1, as shown in FIGS. 9A to 9C. At this time, as shown in FIG. 9B, the second barrier film BM2 is superimposed on the first barrier film BM1 in the boundary portion BP. On the other hand, if the first barrier film BM1 is formed after the formation of the second barrier film BM2, the configuration shown in FIGS. 13A to 13C can be obtained.

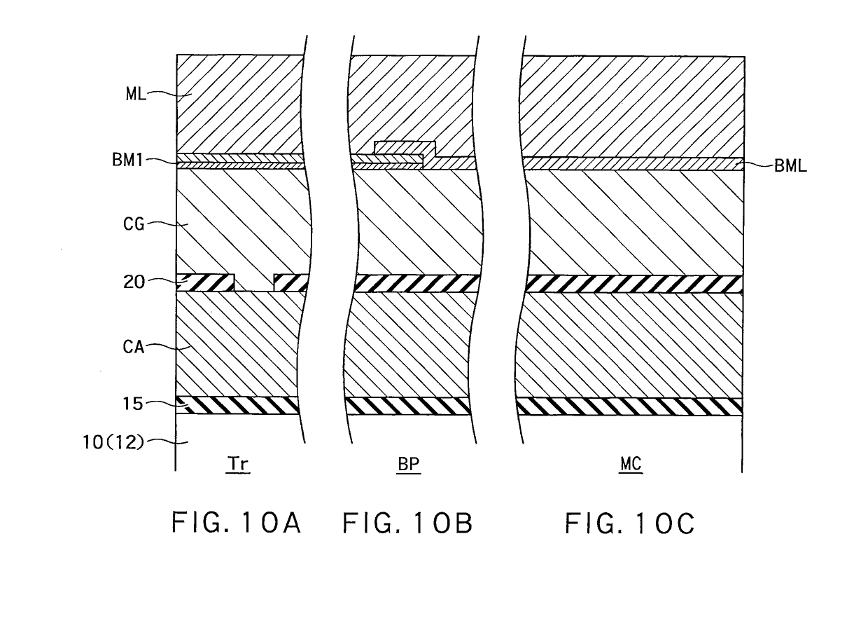

As shown in FIGS. 10A to 10C, the material of the metal layer ML is then deposited on the first and second barrier films BM1 and BM2. The material of the metal layer ML is formed by using, for example, a low resistance metal such as tungsten.

Furthermore, a hard mask (not shown) is formed on the metal layer ML, and the hard mask is processed into a layout pattern using a lithographic technique, a RIE method, and a sidewall transfer method. By using this hard mask as a mask, the materials of the metal layer ML, the first and second barrier films BM1 and BM2, and the gate electrodes (CG and CA) as well as the inter-gate dielectric film 20 are processed. The gate electrodes MCG and G are thereby formed in the memory cell array 1 and the peripheral circuit region 2, respectively, as shown in FIGS. 4A to 4C. Thereafter, an interlayer dielectric film ILD, the bit lines BL, and the like are formed, thereby completing the memory according to the first embodiment.

With the manufacturing method according to the first embodiment, the first barrier film BM1 is formed in the gate electrode G of each transistor Tr in the peripheral circuit region 2, and the second barrier film BM2 different from the first barrier film BM1 is formed in the gate electrode MCG of each memory cell MC. With this process, the first embodiment can realize both an improvement in an operation speed of each transistor Tr in the peripheral circuit region 2 and a reduction in a sheet resistance R_{S} of each word line WL in the memory cell array 1.

Furthermore, in the first embodiment, it suffices to use the contract plugs that reach the metal layer ML and it is unnecessary to use the deep contact plugs that reach up to the charge accumulation layer CA as the contact plugs. Therefore, at the time of forming the contact plugs, there is no need to repeatedly perform the lithographic process and the etching process a plurality of times. This can suppress an increase in the number of manufacturing processes.

### Second Embodiment

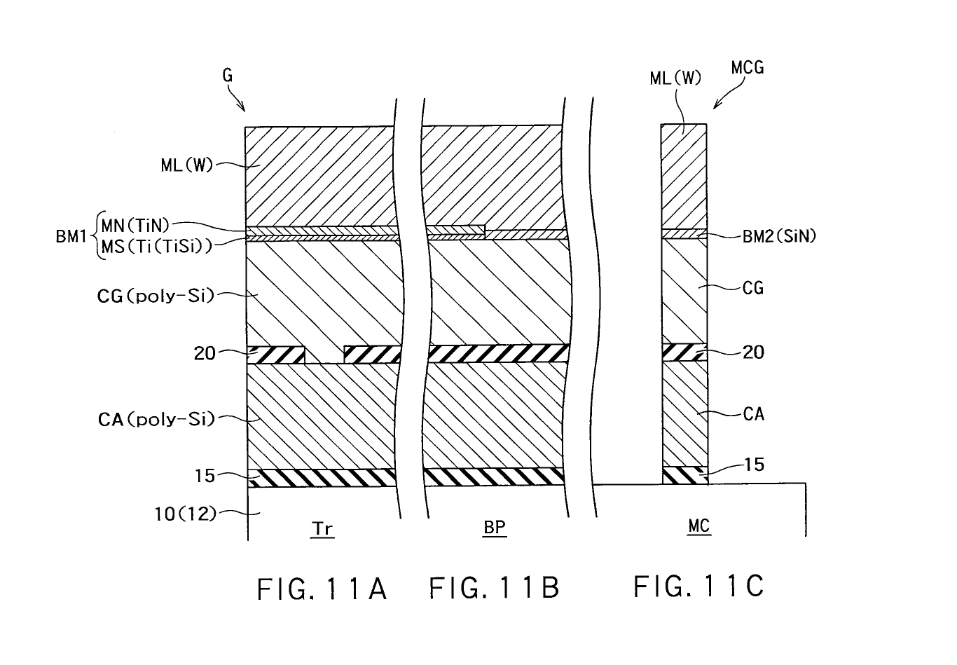

FIGS. 11A to 11C are cross-sectional views showing an example of a configuration of the gate electrode MCG of each memory cell MC, an example of a configuration of the gate electrode G of each transistor Tr, and an example of a configuration of the boundary portion BP between the memory cell array 1 and the peripheral circuit region 2 according to the second embodiment. The second embodiment differs from the first embodiment in that the second barrier film BM2 is formed by using a silicon nitride film. Other configurations of the second embodiment can be identical to corresponding configurations of the first embodiment.

When the second barrier film BM2 includes a silicon nitride film, the interface resistance R_{EI} increases but the sheet resistance R_{S} of the metal layer ML on the second barrier film BM2 decreases similarly to the use of a tungsten nitride film. Therefore, the second embodiment can also achieve effects identical to those of the first embodiment.

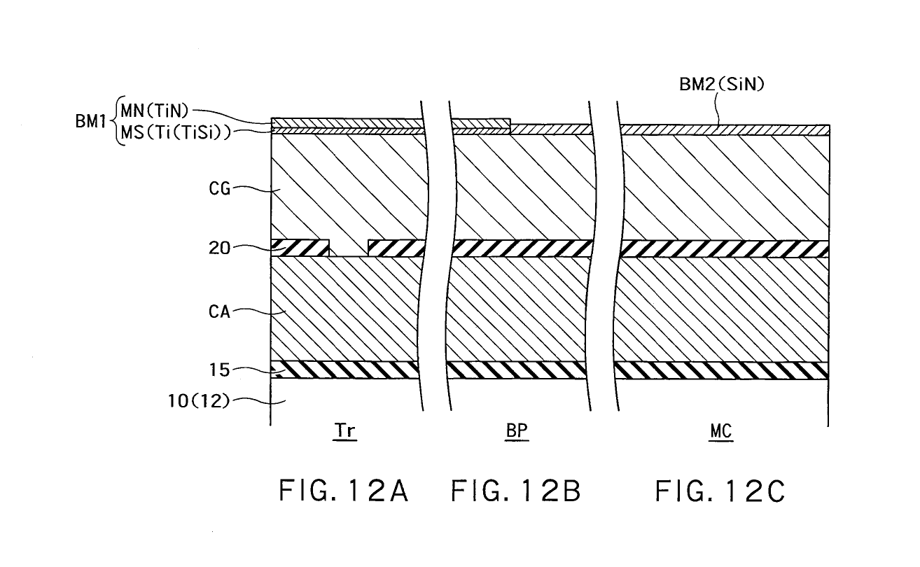

FIGS. 12A to 12C are cross-sectional views showing an example of a manufacturing method of a NAND flash EEPROM according to the second embodiment. After the processes described with reference to FIGS. 7A to 8C, a surface of the control gate CG is nitrided using spike annealing, for example.

As a result, a silicon nitride film is selectively formed as the second barrier film BM2 on the control gate CG in the region of the memory cell array 1, as shown in FIGS. 12A to 12C. Next, as described with reference to FIGS. 10A to 10C, the material of the metal layer ML is deposited on the first and second barrier films BM1 and BM2. Thereafter, the materials of the metal layer ML, the first and second barrier films BM1 and BM2, and the gate electrodes (CG and CA), and the inter-gate dielectric film 20 are processed. The gate electrodes MCG and G are thereby formed in the memory cell array 1 and the peripheral circuit region 2, respectively, as shown in FIGS. 11A to 11C. Thereafter, the interlayer dielectric film ILD, the bit lines BL, and the like are formed, thereby completing the memory according to the second embodiment.

In the second embodiment, there is no need to perform the lithographic process and the etching process to form the second barrier film BM2. Therefore, it is possible to decrease the number of processes of the manufacturing method according to the second embodiment as compared with the manufacturing method according to the first embodiment. Moreover, in the second embodiment, similarly to the first embodiment, the first barrier film BM1 is formed in the gate electrode G of each transistor Tr in the peripheral circuit region 2 and the second barrier film BM2 different from the first barrier film BM1 is formed in the gate electrode MCG of each memory cell MC. Similarly to the first embodiment, the second embodiment can thereby realizing both an improvement in an operation speed of each transistor Tr in the peripheral circuit region 2 and a reduction in a sheet resistance R_{S} of each word line WL in the memory cell array 1.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising:
a semiconductor substrate;
a plurality of memory cells provided on the semiconductor substrate;
peripheral circuits provided on a periphery of the memory cells;
a first barrier film including a first nitride film provided on a first gate electrode of a transistor included in the peripheral circuits;
a second barrier film including a second nitride film different from the first nitride film, the second nitride film being provided on a second gate electrode of the memory cells, respectively; and
metal layers provided on the first and second barrier films, respectively.

2. The device of claim 1, wherein
the first barrier film includes a metal silicide provided on the first gate electrode, and
the first nitride film is provided on the metal silicide.

3. The device of claim 1, wherein
the first barrier film includes a titanium silicide film provided on the first gate electrode, and
the titanium nitride film is provided on the titanium silicide film.

4. The device of claim 1, wherein the first barrier film is a laminated film.

5. The device of claim 1, wherein the second barrier film includes a tungsten nitride film.

6. The device of claim 4, wherein the second barrier film is a single layer film.

7. The device of claim 3, wherein
the first and second barrier films are superimposed on each other in a boundary portion between the memory cell array and the peripheral circuit region.

8. The device of claim 1, wherein the second barrier film includes a silicon nitride film.

9. The device of claim 1, wherein the second gate electrode and the metal layer provided on the second gate electrode function as a word line.

10. The device of claim 1, wherein the second gate electrode includes a charge accumulation layer provided above the semiconductor substrate, and a control gate provided above the charge accumulation layer.

11. The device of claim 5, wherein the metal layer includes tungsten.

12. The device of claim 8, wherein the metal layer includes tungsten.

13. A manufacturing method of a semiconductor storage device comprising:
forming a gate electrode material on a semiconductor substrate;
forming a first barrier film including a first nitride film on the gate electrode material in a peripheral circuit region formed on a periphery of a cell array region including a plurality of memory cells;
forming a second barrier film including a second nitride film different from the first nitride film on the gate electrode material in the cell array region;
depositing a metal layer on the first and second barrier films; and
forming a gate electrode in the peripheral circuit region by processing the metal layer, the first barrier film, and the gate electrode material, and a gate electrode in the memory cell region by processing the metal layer, the second barrier film, and the gate electrode material.

14. The method of claim 13, wherein the second barrier film is formed by nitriding the gate electrode material in the cell array region.

15. The method of claim 13, wherein
the formation of the first barrier film comprises:
forming a metal material on the gate electrode in the peripheral circuit region; and
forming the first nitride film on the metal material.

16. The method of claim 15, wherein
the formation of the first barrier film comprises:
forming a titanium film on the gate electrode in the peripheral circuit region; and
forming a titanium nitride film on the titanium film.

17. The method of claim 16, wherein the second barrier film is formed by depositing a tungsten nitride film on the gate electrode material in the cell array region.

18. The method of claim 17, wherein the metal layer includes tungsten.
